(19) United States
(12) Patent Application Publication
(10) Pub. No.: US 2020/0203327 A1
(43) Pub. Date: Jun. 25, 2020

(54) SEMICONDUCTOR MODULE

(71) Applicant: SUMITOMO ELECTRIC INDUSTRIES, LTD., Osaka (JP)

(72) Inventor: Hirotaka OOMORI, Osaka (JP)

(21) Appl. No.: 16/644,996

(22) PCT Filed: May 11, 2018
(86) PCT No.: PCT/JP2018/018378

§ 371 Date: Mar. 6, 2020

(30) Foreign Application Priority Data
Sep. 15, 2017 (JP) 2017-177869

(51) Int. Cl. H01L 25/16; H01L 23/498; H01L 23/34; H01L 23/00; H01L 25/18; G01K 1/14; G01R 19/00; G01R 29/12

(52) U.S. Cl. CPC H01L 25/16; H01L 23/49811; H01L 23/34; H01L 24/48; H01L 24/49; H01L 2224/49176; G01K 1/14; G01R 19/0092; G01R 29/12; H01L 2224/48091; H01L 25/18

(57) ABSTRACT

A semiconductor module includes a substrate, auxiliary terminal components, and main terminal components. A first component includes a first end situated toward the substrate and a second end situated away from the substrate. A second component includes a third end situated toward the substrate and a fourth end situated away from the substrate. At least one of a condition that the first end and the third end differ in height in a direction perpendicular to the main surface and a condition that a distance between the first end and the third end is greater in a plan view, in a direction in which a portion of an outer perimeter of the substrate opposite the first end and the third end extends, than a distance between the second end and the fourth end is satisfied.

### TECHNICAL FIELD

The disclosures herein relate to a semiconductor module.

The present application claims priority to Japanese application No. 2017-177869 filed on Sep. 15, 2017, the entire contents of which are hereby incorporated by reference.

### BACKGROUND ART

In the field of power semiconductor modules, a semiconductor module has been developed that includes power terminals electrically connected to a semiconductor device and signal terminals electrically connected to the semiconductor device and oriented perpendicularly to the main surface of an insulating substrate (see Patent Document 1, for example).

### RELATED-ART DOCUMENTS

### Patent Document

### [Patent Document 1] Japanese Patent Application Publication No. 2017-005043

### SUMMARY OF THE INVENTION

A semiconductor module according to an embodiment includes a substrate, auxiliary terminal components, and main terminal components. The substrate has, on the main surface thereof, circuitry containing devices. The auxiliary terminal components are electrically connected to the circuitry, and are each capable of conducting a first current. The main terminal components are electrically connected to the circuitry, and are each capable of conducting a second current greater than the first current. The auxiliary terminal components include a first component and a second component. The first component includes a first end situated toward the substrate and a second end situated away from the substrate. The second component includes a third end situated toward the substrate and a fourth end situated away from the substrate. At least one of a condition that the first end and the third end differ in height in a direction perpendicular to the main surface and a condition that a distance between the first end and the third end is greater in a plan view, in a direction in which a portion of an outer perimeter of the substrate opposite the first end and the third end extends, than a distance between the second end and the fourth end is satisfied.

### BRIEF DESCRIPTION OF DRAWINGS

FIG. 1 is a schematic axonometric view illustrating the configuration of a semiconductor module.

FIG. 2 is a schematic plan view of the semiconductor module.

FIG. 3 is a schematic axonometric view illustrating the structure and arrangement of a first component and a second component.

FIG. 4 is a schematic axonometric view illustrating the structure and arrangement of the first component, the second component, a third component, and a fourth component.

FIG. 5 is a schematic plan view illustrating a variation of the semiconductor module of the first embodiment.

### MODE FOR CARRYING OUT THE INVENTION

Terminals provided in a semiconductor module include a main terminal component and an auxiliary terminal component. The auxiliary terminal component is a terminal capable of conducting a first current. The main terminal component is a terminal capable of conducting a second current greater than the first current. Examples of auxiliary terminal components include an auxiliary terminal component connected to a current sensor for detecting current flowing through a semiconductor device embedded in a semiconductor module, an auxiliary terminal component connected to a potential sensor for detecting the potential of a semiconductor device, and an auxiliary terminal component connected to a temperature sensor for detecting the temperature of a semiconductor device. In this manner, a semiconductor module is provided with a plurality of auxiliary terminal components. It is thus preferable, for the purpose of reducing the size of a semiconductor module, to reduce the area for mounting auxiliary terminal components (i.e., the plan-view area for mounting auxiliary terminal components as viewed in a direction perpendicular to the main surface of a substrate on which a semiconductor device is mounted).

Accordingly, it is an object of the present disclosure to provide a semiconductor module that can be made compact by reducing the area for mounting auxiliary terminal components.

### Description of Embodiments of the Present Disclosures

Embodiments of the technologies of the present disclosures will be listed and described first. A semiconductor module of the present disclosures includes a substrate, auxiliary terminal components, and main terminal components. The substrate has, on the main surface thereof, circuitry containing devices. The auxiliary terminal components are electrically connected to the circuitry, and are each capable of conducting a first current. The main terminal components are electrically connected to the circuitry, and are each capable of conducting a second current greater than the first current. The auxiliary terminal components include a first component and a second component. A first component includes a first end situated toward the substrate and a second end situated away from the substrate. A second component includes a third end situated toward the substrate and a fourth end situated away from the substrate. At least one of a condition that the first end and the third end differ in height in a direction perpendicular to the main surface and a condition that a distance between the first end and the third end is greater in a plan view, in a direction in which a portion of an outer perimeter of the substrate opposite the first end and the third end extends, than a distance between the second end and the fourth end is satisfied.

The condition (i.e., condition 1) that the first end and the third end differ in height in the direction (i.e., first direction) perpendicular to the main surface of the substrate is realized, thereby allowing the first end and the third end to be disposed close to each other in a plan view. Further, the condition (i.e., condition 2) that the distance between the first end and the third end is greater in a plan view, in the direction (i.e., second direction) in which the portion of the outer perimeter of the substrate opposite the first end and the third end extends, than the distance between the second end and the fourth end is satisfied, thereby allowing the distance in the second direction between the second end and the fourth end to be shortened.

In the semiconductor module of the present disclosures, at least one of the condition 1 and the condition 2 described above is satisfied. Accordingly, the semiconductor module of the present disclosures allows the area for mounting the auxiliary terminal components to be reduced, so that the semiconductor module can be made compact.

In the above-noted semiconductor module, the condition that the first end and the third end differ in height in the direction perpendicular to the main surface and the condition that the distance between the first end and the third end is greater in a plan view, in the direction in which the portion of the outer perimeter of the substrate opposite the first end and the third end extends, than the distance between the second end and the fourth end may be both satisfied. When the above-noted condition 1 and condition 2 are both satisfied as described above, the semiconductor module can be made more compact.

In the above-noted semiconductor module, a position of the first end and a position of the third end in a plan view may differ in a direction perpendicular to the direction in which the portion of the outer perimeter of the substrate opposite the first end and the third end extends. This arrangement allows wire bonding to be easily made with respect to each of the first end and the third end.

In the above-noted semiconductor module, the devices may include a temperature sensor. One or more of the auxiliary terminal components may be electrically connected to the temperature sensor. This arrangement allows the semiconductor module having the temperature sensor to be made compact.

In the above-noted semiconductor module, the devices may include a current sensor. One or more of the auxiliary terminal components may be electrically connected to the current sensor. This arrangement allows the semiconductor module having the current sensor to be made compact.

In the above-noted semiconductor module, the devices may include a potential sensor. One or more of the auxiliary terminal components may be electrically connected to the potential sensor. This arrangement allows the semiconductor module having the potential sensor to be made compact.

In the above-noted semiconductor module, the circuitry may include a plurality of conductive regions electrically connected to the auxiliary terminal components. The plurality of conductive regions may include a first conductive region electrically connected to the first end and a second conductive region electrically connected to the third end. In a plan view, the position of the first conductive region and the position of the second conductive region may differ in a direction perpendicular to the direction in which the portion of the outer perimeter of the substrate opposite the first end and the third end extends. This arrangement allows the plurality of conductive regions to be placed within a small area on the substrate, so that the semiconductor module can be made compact.

### Details of Embodiments of the Present Disclosures

In the following, an embodiment of a semiconductor module of the present disclosures will be described with reference to the drawings. In the following drawings, the same or corresponding elements are referred to by the same numerals, and a duplicate description thereof will be omitted.

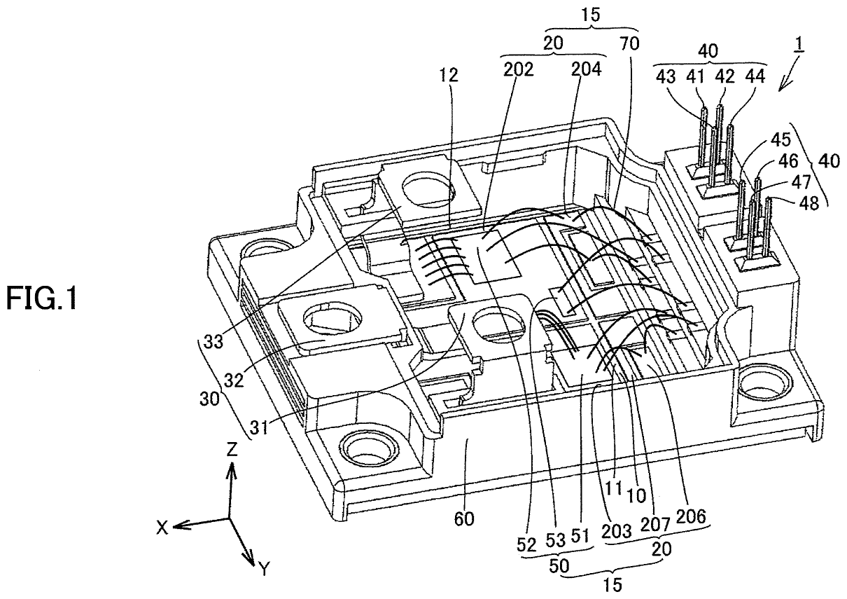

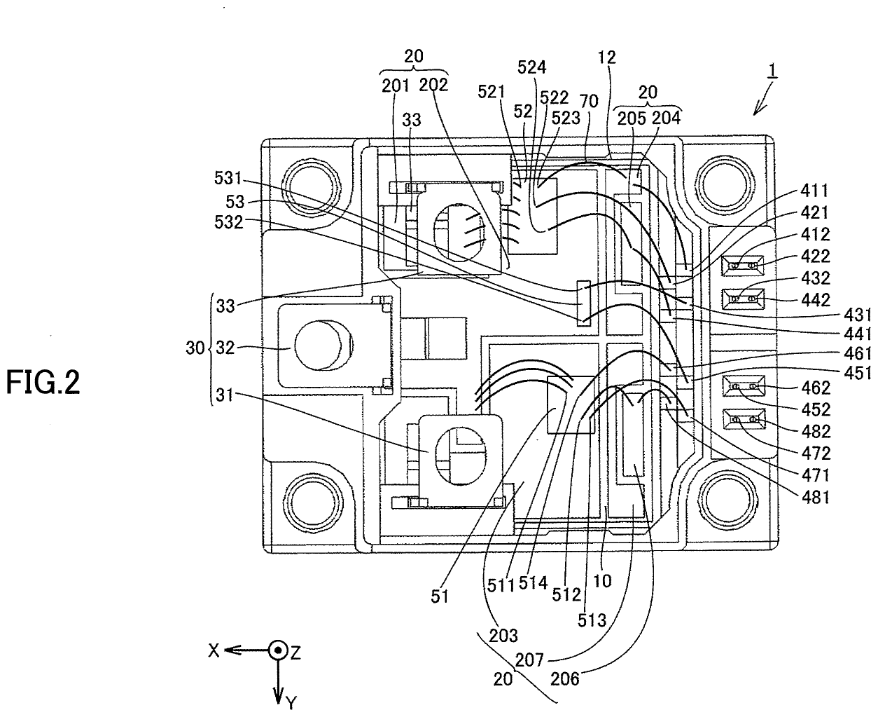

Referring to FIG. 1 and FIG. 2, a semiconductor module 1 includes a substrate 10, circuitry 15, main terminal components 30, auxiliary terminal components 40, and a case 60. In the present embodiment, the semiconductor module 1 is a power semiconductor module. Namely, the semiconductor module 1 is used for the purpose of controlling a large amount of electric power, and is utilized for a power supply or the like. The semiconductor module 1 has an oblong shape in a plan view as viewed in the Z-axis direction in FIG. 2.

The case 60 contains the substrate 10. The substrate 10 has a first main surface 11. The outer perimeter 12 of the substrate 10 forms an oblong shape. In the present embodiment, the substrate 10 is made of an insulating substrate. The substrate 10 may be provided with a heatsink. In the following description, the direction perpendicular to the first main surface 11 of the substrate 10 is referred to as the Z-axis direction, the direction of the long side of the substrate 10 referred to as the Y-axis direction, and the direction of the short side of the substrate 10 referred to as the X-axis direction.

The circuitry 15 is formed on the first main surface 11. The circuitry 15 includes a plurality of conductive regions 20, devices 50, and metallic wires 70. The circuitry 15 is configured such that the conductive regions 20 and the devices 50 are electrically coupled through the wires 70. The conductive regions 20 are formed on the first main surface 11. The conductive regions 20 are made of a material such as an electrically conductive metal. In the present embodiment, the conductive regions 20 are made of copper. The conductive regions 20 include a first conductive region 201, a second conductive region 202, a third conductive region 203, a fourth conductive region 204, a fifth conductive region 205, a sixth conductive region 206, and a seventh conductive region 207.

The devices 50 are disposed on the substrate 10. The devices 50 are disposed on the conductive regions 20. The devices 50 include first devices 51 and 52 and a second device 53. In the present embodiment, the first devices 51 and 52 are vertical semiconductor devices. More specifically, the first devices 51 and 52 are MOSFETs (i.e., metal oxide semiconductor field effect transistors). The second device 53 is a temperature sensor. In the present embodiment, the second device 53 is a thermistor. The second device 53 detects the temperature of the semiconductor module 1.

The first device 51 includes a first source electrode 511, a first gate electrode 512, a first source pad 513, and a first sense pad 514. The first source electrode 511, the first gate electrode 512, the first source pad 513, and the first sense pad 514 are disposed at the positions indicated by their respective reference numbers on the upper surface of the first device 51. For the sake of clarity of illustration, the contours of electrodes and pads are omitted. Hereinafter, the same applies to other devices. The first device 51 is disposed on the third conductive region 203. The drain electrode (not shown) of the first device 51 is electrically connected to the third conductive region 203. The first source pad 513 may be used to measure the potential of the first source electrode 511. The first sense pad 514 may be used to measure the current flowing between the drain electrode and the first source electrode 511 of the first device 51.

The first device 52 includes a second source electrode 521, a second gate electrode 522, a second source pad 523, and a second sense pad 524. The first device 52 is disposed on the second conductive region 202. The drain electrode (not shown) of the first device 52 is electrically connected to the second conductive region 202. The second source pad 523 may be used to measure the potential of the second source electrode 521. The second sense pad 524 may be used to measure the current flowing between the drain electrode and the second source electrode 521 of the first device 52.

The second device 53 includes a first electrode 531 and a second electrode 532. The second device 53 is disposed on the second conductive region 202.

The main terminal components 30 include a first main terminal component 31, a second main terminal component 32, and a third main terminal component 33. The main terminal components 30 are capable of conducting a second current. The second current is greater than a first current, which will be described later. The main terminal components 30 are used to control a high voltage such as a power supply voltage. One example of such main terminal components 30 is a terminal that is connected directly or indirectly to a high-voltage generating power supply to conduct the current therefrom. The main terminal components 30 are made of metal. The main terminal components 30 have a bent plate shape. The first main terminal component 31 is electrically connected to the third conductive region 203. The second main terminal component 32 is electrically connected to the second conductive region 202. The third main terminal component 33 is electrically connected to the first conductive region 201.

The auxiliary terminal components 40 are capable of conducting the first current that is less than the second current. One example of such auxiliary terminal components 40 is a terminal that conducts a control signal for controlling the second current flowing through the main terminal components 30, and is a terminal that conducts a current such as a detection signal used for such control. The auxiliary terminal components 40 are utilized to control a relatively low voltage supplied to a sensor that senses temperature or the like. The auxiliary terminal components 40 are also utilized as a terminal for supplying a gate voltage to a MOSFET, for example. The auxiliary terminal components 40 include a first component 41 and a second component 42. The auxiliary terminal components 40 are disposed along one side of the oblong semiconductor module 1 situated at one end in the X-axis direction. The auxiliary terminal components 40 are situated opposite the side on which the second main terminal component 32 is situated, as viewed relative to the position of the substrate 10.

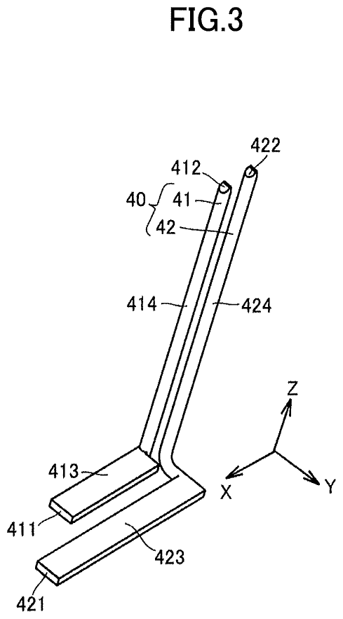

Referring to FIG. 1, FIG. 2, and FIG. 3, the first component 41 includes a first end 411 situated toward the substrate 10 and a second end 412 situated away from the substrate 10. The second component 42 includes a third end 421 situated toward the substrate 10 and a fourth end 422 situated away from the substrate 10.

The first component 41 includes a first plate portion 413 and a first rod portion 414. The first plate portion 413 has a flat plate shape with an oblong planar shape. An end portion at one end of the longitudinal extension of the first plate portion 413 is a first end 411. An end portion at the other end of the longitudinal extension of the first plate portion 413 is connected to the first rod portion 414. An end portion at one end of the first rod portion 414 is a second end 412. An end portion at the other end of the first rod portion 414 is connected to the first plate portion 413. The first rod portion 414 is configured to extend along the Z-axis direction.

The second component 42 includes a second plate portion 423 and a second rod portion 424. The second plate portion 423 has a flat plate shape with an oblong planar shape. An end portion at one end of the longitudinal extension of the second plate portion 423 is a third end 421. An end portion at the other end of the longitudinal extension of the second plate portion 423 is connected to the second rod portion 424. An end portion at one end of the second rod portion 424 is a fourth end 422. An end portion at the other end of the second rod portion 424 is connected to the second plate portion 423. The second rod portion 424 is configured to extend in a direction along the first rod portion 414 (i.e., in the Z-axis direction). In a plan view as seen in the Z-axis direction, the lower end of the second rod portion 424 (“the other end” noted above) is bent to extend in the direction (i.e., the Y-axis direction) in which a portion of the outer perimeter of the substrate 10 opposite the first end 411 and the third end 421 extends, with the tip thereof connected to the second plate portion 423.

The auxiliary terminal components 40 include third and fourth components 43 and 44, fifth and sixth components 45 and 46, and seventh and eighth components 47 and 48 in addition to the first and second components 41 and 42. The third component 43, the fifth component 45, and the seventh component 47 have the same or similar structure as the first component 41. The fourth component 44, the sixth component 46, and the eighth component 48 have the same or similar structure as the second component 42.

The third component 43 includes a fifth end 431 situated toward the substrate 10 and a sixth end 432 situated away from the substrate 10. The fourth component 44 includes a seventh end 441 situated toward the substrate 10 and an eighth end 442 situated away from the substrate 10. The fifth component 45 includes a ninth end 451 situated toward the substrate 10 and a tenth end 452 situated away from the substrate 10. The sixth component 46 includes an eleventh end 461 situated toward the substrate 10 and a twelfth end 462 situated away from the substrate 10. The seventh component 47 includes a thirteenth end 471 situated toward the substrate 10 and a fourteenth end 472 situated away from the substrate 10. The eighth component 48 includes a fifteenth end 481 situated toward the substrate 10 and a sixteenth end 482 situated away from the substrate 10.

Referring to FIG. 1 and FIG. 2, in a plan view as seen in the Z-axis direction, the second end 412 and the fourth end 422 are disposed in alignment with the direction (i.e., the X-axis direction) that intersects (i.e., is perpendicular to) the direction (i.e., the Y-axis direction) in which a portion of the outer perimeter 12 of the substrate 10 opposite the first end 411 and the third end 421 extends. Similarly, the sixth end 432 and the eighth end 442 are disposed in alignment with the X-axis direction. The tenth end 452 and the twelfth end 462 are disposed in alignment with the X-axis direction. The fourteenth end 472 and the sixteenth end 482 are disposed in alignment with the X-axis direction.

The first source electrode 511 of the first device 51 and the second conductive region 202 are electrically coupled through one or more wires 70. The first gate electrode 512 of the first device 51 and the sixth conductive region 206 are electrically coupled through a wire 70. The sixth conductive region 206 and the fifteenth end 481 are electrically coupled through a wire 70. The first source pad 513 of the first device 51 and the thirteenth end 471 are electrically coupled through a wire 70. The fourteenth end 472 is electrically connected to a potential sensor that is disposed outside the semiconductor module 1 to detect an electric potential. The first sense pad 514 of the first device 51 and the eleventh end 461 are electrically coupled through a wire 70. The twelfth end 462 is electrically connected to a current sensor that is disposed outside the semiconductor module 1 to detect an electric current.

The second source electrode 521 of the first device 52 and the first conductive region 201 are electrically coupled through one or more wires 70. The second gate electrode 522 of the first device 52 and the third end 421 are electrically coupled through a wire 70. The second source pad 523 of the first device 52 and the fourth conductive region 204 are electrically coupled through a wire 70. The fourth conductive region 204 and the first end 411 are electrically coupled through a wire 70. The second sense pad 524 of the first device 52 and the fifth conductive region 205 are electrically coupled through a wire 70. The fifth conductive region 205 and the seventh end 441 are electrically coupled through a wire 70. The first electrode 531 of the second device 53 and the fifth end 431 are electrically coupled through a wire 70. The second electrode 532 of the second device 53 and the ninth end 451 are electrically coupled through a wire 70.

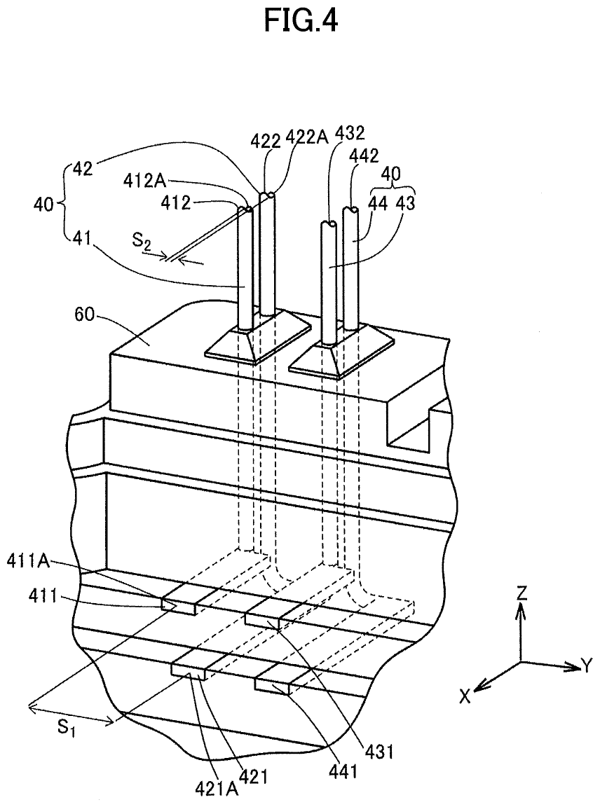

Referring to FIG. 4, the first component 41 and the second component 42 are disposed in the sidewall of the case 60. The first end 411 and the second end 412 are exposed from the sidewall of the case 60. The third end 421 and the fourth end 422 are exposed from the sidewall of the case 60. The third component 43 and the fourth component 44 are disposed in the sidewall of the case 60. The fifth end 431 and the sixth end 432 are exposed from the sidewall of the case 60. The seventh end 441 and the eighth end 442 are exposed from the sidewall of the case 60.

Referring to FIG. 1 and FIG. 4, the condition (i.e., condition 1) that the height of the first end 411 and the height of the third end 421 are different in the Z-axis direction is realized. More specifically, the condition that a center 411A, in the Y-axis direction, of the closest portion of the first end 411 to the substrate 10 differs in height from a center 421A, in the Y-axis direction, of the closest portion of the third end 421 to the substrate 10 is realized. The third and fourth components 43 and 44, the fifth and sixth components 45 and 46, and the seventh and eighth components 47 and 48 are arranged in the same manner as the first and second components 41 and 42, respectively.

In a plan view as seen in the Z-axis direction, the condition (i.e., condition 2) that the distance between the first end 411 and the third end 421 in the Y-axis direction is greater than the distance between the second end 412 and the fourth end 422 in the Y-axis direction is realized. This is because the lower end of the second rod portion 424 is bent to point in the Y-axis direction as previously described. It may be noted that the distance between the first end 411 and the third end 421 in the Y-axis direction refers to a distance S1 in the Y-axis direction from the center 411A in the Y-axis direction to the center 421A in the Y-axis direction. Further, the distance between the second end 412 and the fourth end 422 in the Y-axis direction refers to a distance S2 in the Y-axis direction between a center 412A, in the Y-axis direction, of the farthest portion of the second end 412 from the substrate 10 and a center 422A, in the Y-axis direction, of the farthest portion of the fourth end 422 from the substrate 10. In the present embodiment, S2 is 0. The third and fourth components 43 and 44, the fifth and sixth components 45 and 46, and the seventh and eighth components 47 and 48 are arranged in the same manner as the first and second components 41 and 42, respectively.

In a plan view as seen in the Z-axis direction, the position of the first end 411 and the position of the third end 421 in the X-axis direction are different from each other. This arrangement allows wire bonding to be easily made with respect to each of the first end 411 and the third end 421. The third and fourth components 43 and 44, the fifth and sixth components 45 and 46, and the seventh and eighth components 47 and 48 are arranged in the same manner as the first and second components 41 and 42, respectively.

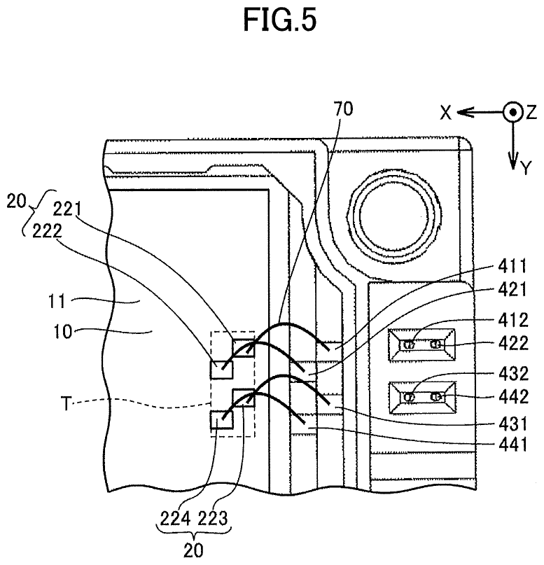

FIG. 5 illustrates a variation of the present embodiment. Referring to FIG. 5, this variation is such that a first conductive region 221 and a second conductive region 222 are disposed on the first main surface 11 of the substrate 10. The first conductive region 221 and the second conductive region 222 have a rectangular shape. The first conductive region 221 and the first end 411 are electrically coupled through a wire 70. The second conductive region 222 and the third end 421 are electrically coupled through a wire 70.

On the first main surface 11, a third conductive region 223 and a fourth conductive region 224 are disposed in addition to the first conductive region 221 and the second conductive region 222. The third conductive region 223 and the fourth conductive region 224 have a rectangular shape. The third conductive region 223 and the fifth end 431 are electrically coupled through a wire 70. The fourth conductive region 224 and the seventh end 441 are electrically coupled through a wire 70. The first conductive region 221, the second conductive region 222, the third conductive region 223, and the fourth conductive region 224 are arranged such as to be within the confines of a region T illustrated in FIG. 5.

In a plan view as seen in the Z-axis direction, the position of the first conductive region 221 and the position of the second conductive region 222 in the X-axis direction are different from each other. Similarly, in a plan view as seen in the Z-axis direction, the position of the third conductive region 223 and the position of the fourth conductive region 224 in the X-axis direction are different from each other. This arrangement allows a plurality of conductive regions to be placed within a small area on the substrate, so that the semiconductor module 1 can be made compact.

In the semiconductor module 1 according to the present embodiment, the condition (i.e., condition 1) that the height of the first end 411 and the height of the third end 421 are different from each other in the Z-axis direction is realized, thereby allowing the first end 411 and the third end 421 to be disposed close to each other in a plan view. Similarly, the fifth end 431 and the seventh end 441 can be positioned close to each other. The ninth end 451 and the eleventh end 461 can be disposed close to each other. The thirteenth end 471 and the fifteenth end 481 can be disposed close to each other.

In a plan view as seen in the Z-axis direction, the condition (i.e., condition 2) that the distance between the first end 411 and the third end 421 in the Y-axis direction is greater than the distance between the second end 412 and the fourth end 422 in the Y-axis direction is realized, thereby allowing a distance between the second end 412 and the fourth end 422 in the Y-axis direction to be shortened. Similarly, the distance between the sixth end 432 and the eighth end 442 can be shortened. The distance between the tenth end 452 and the twelfth end 462 can be shortened. The distance between the fourteenth end 472 and the sixteenth end 482 can be shortened.

In this manner, the semiconductor module 1 according to the present embodiment satisfies the condition 1 and the condition 2 described above. Accordingly, the semiconductor module 1 of the present embodiment allows the area for mounting the auxiliary terminal components 40 to be reduced, so that the semiconductor module 1 can be made compact.

In the embodiment described heretofore, the devices 50 include a temperature sensor that is a second device 53. The third component 43 and the fifth component 45, which are auxiliary terminal components 40, are electrically connected to the temperature sensor. This arrangement allows the semiconductor module 1 having the temperature sensor to be made compact.

The above-described embodiment has been directed to a case in which the plan-view shape of the semiconductor module 1 as viewed in the Z-axis direction is an oblong shape. The semiconductor module 1 is not limited to this shape, and various shapes may be employed depending on the application or the like.

The above-described embodiment has been directed to a case in which the shape of the outer perimeter 12 of the substrate 10 is an oblong. The outer perimeter 12 of the substrate 10 is not limited to such a shape. Various shapes may be employed by taking into account the ease of placement of components disposed on the substrate 10 as well as the arrangement of peripheral components and the like.

The above-described embodiment has been directed to a case in which the devices 50 include the first devices 51 and 52 that are a MOSFET. The devices 50 are not limited to these examples, and may include an SBD (Schottky barrier diode). The devices 50 may include both a MOSFET and an SBD. The above-described embodiments have been directed to a case in which the devices 50 include the second device 53 that is a temperature sensor. The devices 50 are not limited to this example, and may include a current sensor for detecting an electric current or a potential sensor for detecting an electric potential. The devices 50 may include a temperature sensor, a current sensor, and a potential sensor.

The above-described embodiment has been directed to a configuration in which the auxiliary terminal components 40 are disposed opposite the side where the second main terminal component 32 is disposed, with respect to the position of the substrate 10. The semiconductor module 1 of the present application is not limited to this example, and various configurations may be employed.

The above-described embodiment has been directed to a configuration in which the auxiliary terminal components 40 include the first and second components 41 and 42, the third and fourth components 43 and 44, the fifth and sixth components 45 and 46, and the seventh and eighth components 47 and 48. The auxiliary terminal components 40 are not limited to these, and various configurations may be employed depending on the application.

The disclosed embodiment has been directed to a situation in which the condition 1 and the condition 2 are both realized. Notwithstanding this, at least one of the condition 1 and the condition 2 may be realized.

All the embodiments disclosed herein are examples only, and should be interpreted as non-limiting in any aspects. The scope of the present invention is not defined by the descriptions provided heretofore, but is defined by the claims. Any modifications representing and within the equivalent scope of the claims are intended within the scope of the present invention.

### DESCRIPTION OF REFERENCE SYMBOLS

1 semiconductor module
10 substrate
11 first main surface
12 outer perimeter
15 circuitry
20 conductive region
201 first conductive region
202 second conductive region
203 third conductive region
204 fourth conductive region
205 fifth conductive region
206 sixth conductive region
207 seventh conductive region
221 first conductive region
222 second conductive region
223 third conductive region
224 fourth conductive region
30 main terminal component
31 first main terminal component
32 second main terminal component
33 third main terminal component
40 auxiliary terminal component
41 first component
411 first end
411A center in the Y-axis direction
412 second end
412A center in the Y-axis direction
413 first plate portion
414 first rod portion
42 second component
421 third end
421A center in the Y-axis direction
422 fourth end
422A center in the Y-axis direction
423 second plate portion
424 second rod portion
43 third component
431 fifth end
432 sixth end
44 fourth component
441 seventh end
442 eighth end
45 fifth component
451 ninth end
452 tenth end
46 sixth component
461 eleventh end
462 twelfth end
47 seventh component
471 thirteenth end
472 fourteenth end
48 eighth component
481 fifteenth end
482 sixteenth end
50 device
51, 52 first device
511 first source electrode
512 first gate electrode
513 first source pad
514 first sense pad
521 second source electrode
522 second gate electrode
523 second source pad
524 second sense pad
53 second device
531 first electrode
532 second electrode
60 case
70 wire

1. A semiconductor module, comprising:
a substrate having a main surface on which a circuit including one or more devices is formed;
auxiliary terminal components electrically connected to the circuit and each capable of conducting a first current; and
main terminal components electrically connected to the circuit and each capable of conducting a second current greater than the first current,
wherein the auxiliary terminal components include a first component and a second component,
wherein the first component includes a first end situated toward the substrate and a second end situated away from the substrate,
wherein the second component includes a third end situated toward the substrate and a fourth end situated away from the substrate, and
wherein at least one of a condition that the first end and the third end differs in height in a direction perpendicular to the main surface and a condition that a distance between the first end and the third end is greater in a plan view, in a direction in which a portion of an outer perimeter of the substrate opposite the first end and the third end extends, than a distance between the second end and the fourth end is satisfied.

2. The semiconductor module as claimed in claim 1, wherein the condition that the first end and the third end differs in height in the direction perpendicular to the main surface and the condition that the distance between the first end and the third end is greater in a plan view, in the direction in which the portion of the outer perimeter of the substrate opposite the first end and the third end extends, than the distance between the second end and the fourth end are both satisfied.

3. The semiconductor module as claimed in claim 1, wherein in a plan view, a position of the first end and a position of the third end differs in a direction perpendicular to the direction in which the portion of the outer perimeter of the substrate opposite the first end and the third end extends.

4. The semiconductor module as claimed in claim 1, wherein the one or more devices include a temperature sensor, and
wherein one or more of the auxiliary terminal components are electrically connected to the temperature sensor.

5. The semiconductor module as claimed in claim 1, wherein the one or more devices include a current sensor, and
wherein one or more of the auxiliary terminal components are electrically connected to the current sensor.

6. The semiconductor module as claimed in claim 1, wherein the one or more devices include a potential sensor, and
wherein one or more of the auxiliary terminal components are electrically connected to the potential sensor.

7. The semiconductor module as claimed in claim 1, wherein the circuit further includes a plurality of conductive regions electrically connected to the auxiliary terminal components,
wherein the plurality of conductive regions include a first conductive region electrically connected to the first end and a second conductive region electrically connected to the third end, and
wherein in a plan view, a position of the first conductive region and a position of the second conductive region differs in a direction perpendicular to the direction in which the portion of the outer perimeter of the substrate opposite the first end and the third end extends.

8. The semiconductor module as claimed in claim 2, wherein in a plan view, a position of the first end and a position of the third end differs in a direction perpendicular to the direction in which the portion of the outer perimeter of the substrate opposite the first end and the third end extends.

9. The semiconductor module as claimed in claim 2, wherein the one or more devices include a temperature sensor, and
wherein one or more of the auxiliary terminal components are electrically connected to the temperature sensor.

10. The semiconductor module as claimed in claim 3, wherein the one or more devices include a temperature sensor, and
wherein one or more of the auxiliary terminal components are electrically connected to the temperature sensor.

11. The semiconductor module as claimed in claim 2, wherein the one or more devices include a current sensor, and
wherein one or more of the auxiliary terminal components are electrically connected to the current sensor.

12. The semiconductor module as claimed in claim 3, wherein the one or more devices include a current sensor, and
wherein one or more of the auxiliary terminal components are electrically connected to the current sensor.

13. The semiconductor module as claimed in claim 2, wherein the one or more devices include a potential sensor, and
wherein one or more of the auxiliary terminal components are electrically connected to the potential sensor.

14. The semiconductor module as claimed in claim 3, wherein the one or more devices include a potential sensor, and
wherein one or more of the auxiliary terminal components are electrically connected to the potential sensor.

15. The semiconductor module as claimed in claim 2, wherein the circuit further includes a plurality of conductive regions electrically connected to the auxiliary terminal components,
wherein the plurality of conductive regions include a first conductive region electrically connected to the first end and a second conductive region electrically connected to the third end, and
wherein in a plan view, a position of the first conductive region and a position of the second conductive region differs in a direction perpendicular to the direction in which the portion of the outer perimeter of the substrate opposite the first end and the third end extends.

16. The semiconductor module as claimed in claim 3, wherein the circuit further includes a plurality of conductive regions electrically connected to the auxiliary terminal components,
wherein the plurality of conductive regions include a first conductive region electrically connected to the first end and a second conductive region electrically connected to the third end, and
wherein in a plan view, a position of the first conductive region and a position of the second conductive region differs in a direction perpendicular to the direction in which the portion of the outer perimeter of the substrate opposite the first end and the third end extends.

17. The semiconductor module as claimed in claim 4, wherein the circuit further includes a plurality of conductive regions electrically connected to the auxiliary terminal components,
wherein the plurality of conductive regions include a first conductive region electrically connected to the first end and a second conductive region electrically connected to the third end, and
wherein in a plan view, a position of the first conductive region and a position of the second conductive region differs in a direction perpendicular to the direction in which the portion of the outer perimeter of the substrate opposite the first end and the third end extends.

18. The semiconductor module as claimed in claim 5, wherein the circuit further includes a plurality of conductive regions electrically connected to the auxiliary terminal components,
wherein the plurality of conductive regions include a first conductive region electrically connected to the first end and a second conductive region electrically connected to the third end, and
wherein in a plan view, a position of the first conductive region and a position of the second conductive region differs in a direction perpendicular to the direction in which the portion of the outer perimeter of the substrate opposite the first end and the third end extends.

19. The semiconductor module as claimed in claim 6, wherein the circuit further includes a plurality of conductive regions electrically connected to the auxiliary terminal components,
wherein the plurality of conductive regions include a first conductive region electrically connected to the first end and a second conductive region electrically connected to the third end, and
wherein in a plan view, a position of the first conductive region and a position of the second conductive region differs in a direction perpendicular to the direction in which the portion of the outer perimeter of the substrate opposite the first end and the third end extends.
